(19) United States
(12) Patent Application Publication
(10) Pub. No.: US 2026/0329675 A1
(43) Pub. Date: Oct. 22, 2026

(54) INFORMATION PROCESSING DEVICE AND INFORMATION PROCESSING SYSTEM

(71) Applicant: Renesas Electronics Corporation, Tokyo (JP)

(72) Inventors: Shunsuke OKUMURA, Tokyo (JP); Koichi NOSE, Tokyo (JP); Masayuki SHIMOBEPPU, Tokyo (JP)

(21) Appl. No.: 19/638,398

(22) Filed: Apr. 3, 2026

(30) Foreign Application Priority Data
Apr. 16, 2025 (JP) 2025-067417

(51) Int. Cl. G06F 9/54; G06F 9/50

(52) U.S. Cl. CPC G06F 9/544; G06F 9/5027; G06F 2209/543

(57) ABSTRACT

An information processing device includes a dynamically reconfigurable processor capable of dynamically reconfiguring processing content, an accelerator configured to speed up inference of an AI model, a shared buffer provided between the dynamically reconfigurable processor and the accelerator and connected thereto by dedicated first and second buses, respectively, a shared bus connected to the dynamically reconfigurable processor, the accelerator, and the shared buffer, and a transfer circuit connected to an external memory and capable of transferring data using the shared bus. A calculation result of the accelerator is stored in the shared buffer via the second bus, the dynamically reconfigurable processor receives the calculation result of the accelerator stored in the shared buffer via the first bus and compresses the received calculation result, and the transfer circuit transfers compressed data via the shared bus to be stored in the external memory.

### CROSS-REFERENCE TO RELATED APPLICATIONS

The disclosure of Japanese Patent Application No. 2025-067417 filed on Apr. 16, 2025 including the specification, drawings and abstract is incorporated herein by reference in its entirety.

### BACKGROUND

This disclosure relates to an information processing device, and relates to an information processing device and an information processing system used for AI learning.

Devices that perform calculation processing include a dynamically reconfigurable processor (DRP: also referred to as an array-type processor) having high processing performance other than a central processing unit (CPU). The dynamically reconfigurable processor is a processor capable of dynamically reconfiguring a circuit by dynamically switching calculation content of each of a plurality of processor elements and a connection relationship between the plurality of processor elements in accordance with sequentially given operation instructions.

There is disclosed a technique listed below.

Japanese Unexamined Patent Application Publication No. 2019-219753

For example, Patent Document 1 discloses processing in which DRP is used in large-scale calculation processing such as deep learning processing.

### SUMMARY

On the other hand, further improvement has been required to perform high-speed data processing. This disclosure provides an information processing device and an information processing system capable of performing high-speed data processing.

Other problems and novel features will become apparent from description of this specification and the accompanying drawings.

An information processing device according to this disclosure includes a dynamically reconfigurable processor capable of dynamically reconfiguring processing content, an accelerator configured to speed up inference of an AI model, a dynamically reconfigurable processor, a shared buffer, a shared bus, and a transfer circuit. The shared buffer is provided between the dynamically reconfigurable processor and the accelerator and connected thereto by dedicated first and second buses, respectively. The shared bus is connected to the dynamically reconfigurable processor, the accelerator, and the shared buffer. The transfer circuit is connected to an external memory and capable of transferring data using the shared bus. A calculation result of the accelerator is stored in the shared buffer via the second bus, the dynamically reconfigurable processor receives the calculation result of the accelerator stored in the shared buffer via the first bus and compresses the received calculation result, and the transfer circuit transfers compressed data via the shared bus to be stored in the external memory.

An information processing system according to this disclosure includes a dynamically reconfigurable processor capable of dynamically reconfiguring processing content, an accelerator configured to speed up inference of an AI model, a dynamically reconfigurable processor, a shared buffer, a shared bus, and a transfer circuit. The shared buffer is provided between the dynamically reconfigurable processor and the accelerator and connected thereto by dedicated first and second buses, respectively. The shared bus is connected to the dynamically reconfigurable processor, the accelerator, and the shared buffer. The transfer circuit is connected to an external memory and capable of transferring data using the shared bus. A calculation result of the accelerator is stored in the shared buffer via the second bus, the dynamically reconfigurable processor receives the calculation result of the accelerator stored in the shared buffer via the first bus and compresses the received calculation result, and the transfer circuit transfers compressed data via the shared bus to be stored in the external memory.

The information processing device and the information processing system according to this disclosure can perform high-speed data processing.

### BRIEF DESCRIPTION OF THE DRAWINGS

FIG. 1 is a block diagram illustrating a hardware configuration of an information processing system 1 according to a first embodiment.

FIG. 2 is a flowchart illustrating a calculation processing operation of deep learning using an AI accelerator 140 according to the first embodiment.

FIG. 3 is a flowchart illustrating processing of an MPU 100 according to the first embodiment.

FIG. 4A and FIG. 4B are diagrams illustrating a flow (part 1) of the processing according to the first embodiment.

FIG. 5A and FIG. 5B are diagrams illustrating the flow (part 2) of the processing according to the first embodiment.

FIG. 6A and FIG. 6B are diagrams illustrating the flow (part 3) of the processing according to the first embodiment.

FIG. 7A and FIG. 7B are diagrams illustrating the flow (part 4) of the processing according to the first embodiment.

FIG. 8A and FIG. 8B are diagrams illustrating the flow (part 5) of the processing according to the first embodiment.

FIG. 9A and FIG. 9B are diagrams illustrating the flow (part 6) of the processing according to the first embodiment.

FIG. 10A and FIG. 10B are diagrams illustrating the flow (part 7) of the processing according to the first embodiment.

FIG. 11A and FIG. 11B are diagrams illustrating the flow (part 8) of the processing according to the first embodiment.

FIG. 12A and FIG. 12B are diagrams illustrating the flow (part 9) of the processing according to the first embodiment.

FIG. 13A and FIG. 13B are diagrams illustrating the flow (part 10) of the processing according to the first embodiment.

FIG. 14 is a diagram illustrating an example of compression processing performed by a dynamically reconfigurable circuit 120 according to the first embodiment.

FIG. 15A and FIG. 15B are diagrams illustrating another example of compression processing performed by the dynamically reconfigurable circuit 120 according to the first embodiment.

FIG. 16A and FIG. 16B are diagrams illustrating a processing time of the information processing system 1 according to a comparative example and the first embodiment.

FIG. 17 is a block diagram illustrating a hardware configuration of an information processing system 1# according to a second embodiment.

FIG. 18 is a block diagram illustrating a hardware configuration of an information processing system 1A according to a third embodiment.

FIG. 19 is a flowchart illustrating a calculation processing operation of deep learning using an AI accelerator 140 according to a fourth embodiment.

FIG. 20 is a diagram illustrating a hardware configuration of an information processing system 1B according to the fourth embodiment.

FIG. 21 is a flowchart illustrating processing of the MPU 100 according to the fourth embodiment.

### DETAILED DESCRIPTION

Hereinafter, embodiments will be described in detail with reference to the drawings. In the drawings, the same or corresponding parts are denoted by the same reference numerals, and the description thereof will not be repeated.

### First Embodiment

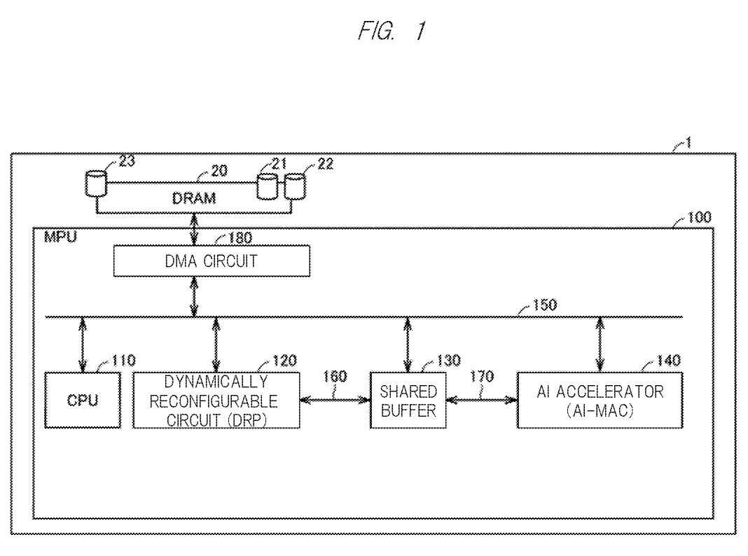

FIG. 1 is a block diagram illustrating a hardware configuration of an information processing system 1 according to a first embodiment. Referring to FIG. 1, the information processing system 1 includes a dynamic random access memory (DRAM) 20 and a micro processing unit (MPU) 100 that is an information processing device. In the present example, the information processing system 1 with a configuration including an MPU that is one information processing device will be described, but it may have a configuration including a plurality of information processing devices operating in cooperation. The MPU 100 includes a central processing unit (CPU) 110, a dynamically reconfigurable circuit (DRP) 120, a shared buffer 130, an AI accelerator (AI-MAC) 140, a shared bus 150, a direct memory access (DMA) circuit 180, and dedicated buses 160 and 170. The DMA circuit 180 is a circuit that is connected to the DRAM 20 and can access the DRAM 20 to transfer data to another circuit at a high speed via the shared bus 150. The DMA circuit 180 is a circuit capable of performing high-speed transfer from another circuit to the DRAM 20 via the shared bus 150.

The shared bus 150 is connected to each circuit of each unit of the MPU 100. The DRP 120 includes a plurality of processor elements formed in an array, a plurality of switch elements formed corresponding to the plurality of processor elements, and a state management unit. The state management unit issues an instruction pointer determined in advance by a program to each processor element. Each processor element includes, for example, at least an instruction memory and a calculation unit. The calculation unit performs calculation processing in accordance with an operation instruction designated by an instruction pointer from the state management unit among a plurality of operation instructions stored in the instruction memory. The calculation unit is, for example, a 16-bit calculator that performs calculation processing on data having a 16-bit width, but may be a calculator that performs calculation processing on data having other bit widths. Alternatively, the calculation unit may include a plurality of calculators. Also, each switch element sets a connection relationship between a corresponding processor element and another processor element in accordance with an operation instruction read from the instruction memory of the corresponding processor element. As a result, the DRP 120 can dynamically switch the circuit configuration in accordance with sequentially given operation instructions. In the present example, for example, the DRP 120 operates as a compression circuit that compresses data or a decompression circuit that decompresses compressed data.

The AI accelerator 140 is a circuit that speeds up inference of an AI model. The calculation processing is performed in parallel in accordance with the AI model. The AI accelerator 140 receives input data from the shared buffer 130, performs calculation processing, and stores the calculation processing result in the shared buffer 130 again. In the present example, the dedicated bus 170 is provided between the shared buffer 130 and the AI accelerator 140 such that data can be exchanged at a high speed.

The shared buffer 130 is provided between the DRP 120 and the AI-MAC 140, is connected by the dedicated buses 160 and 170, and is provided so as to be able to exchange data at a high speed. Although connected to the shared bus 150, it is possible to exchange data with a connection destination at a high speed by using the dedicated buses 160 and 170.

The CPU 110 gives instructions to execute various operations. The DRAM 20 that is an external memory stores software programs, data, and the like for implementing various functions. In the present example, for example, the DRAM 20 stores a compression program 21 that causes the dynamically reconfigurable circuit 120 to function as a compression circuit, a decompression program 22 that causes the dynamically reconfigurable circuit 120 to function as a decompression circuit corresponding to the compression circuit, and AI model data 23 of the AI accelerator 140. The AI model is configured by connecting a plurality of layers, and the AI model data has data for each layer.

Note that the information processing system may be connected to a display device and an input device. The display device performs screen display. The input device inputs a user's instruction to the information processing system. The input device is, for example, a keyboard that receives an input of character information from a user, a mouse that designates any position on a screen of the display device and receives an input of an instruction corresponding to an icon or the like displayed at the position, or the like. However, the devices connected to the information processing system 1 are not limited thereto.

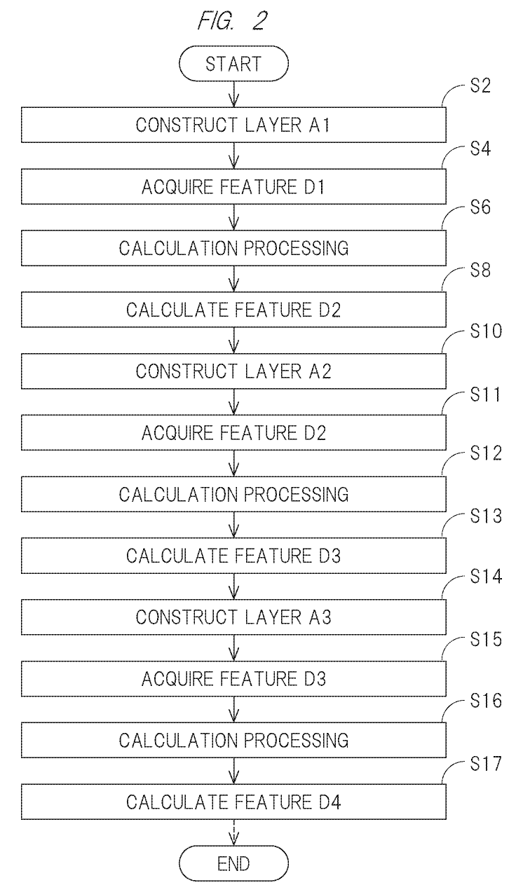

FIG. 2 is a flowchart illustrating a calculation processing operation of deep learning using the AI accelerator 140 according to the first embodiment. Referring to FIG. 2, the AI accelerator 140 constructs a layer A1 of the layer model of the AI model (step S2). Subsequently, the AI accelerator 140 acquires a feature D1 (step S4). Subsequently, the AI accelerator 140 performs calculation processing based on the layer A1 of the AI model using the acquired feature D1 (step S6). Specifically, a procedure of performing a product-sum operation of multiplying input data by a weight, performing an operation such as activation on a result of the product-sum operation, and outputting a calculation result is taken.

By the processing, the AI accelerator 140 calculates a feature D2 (step S8). Subsequently, the AI accelerator 140 constructs a layer A2 of the AI model (step S10). Subsequently, the AI accelerator 140 acquires the feature D2 (step S11). Subsequently, the AI accelerator 140 performs calculation processing based on the layer A2 of the AI model using the acquired feature D2 (step S12). A procedure of performing a product-sum operation of multiplying input data by a weight, performing an operation such as activation on a result of the product-sum operation, and outputting a calculation result is taken.

By the above processing, the AI accelerator 140 calculates a feature D3 (step S13). Subsequently, the AI accelerator 140 constructs a layer A3 of the AI model (step S14). Subsequently, the AI accelerator 140 acquires the feature D3 (step S15). Subsequently, the AI accelerator 140 performs calculation processing based on the layer A3 of the AI model using the acquired feature D3 (step S16). A procedure of performing a product-sum operation of multiplying input data by a weight, performing an operation such as activation on a result of the product-sum operation, and outputting a calculation result is taken. By the above processing, the AI accelerator 140 calculates a feature D4 (step S17). Necessary features can be extracted by sequentially repeating the same procedure.

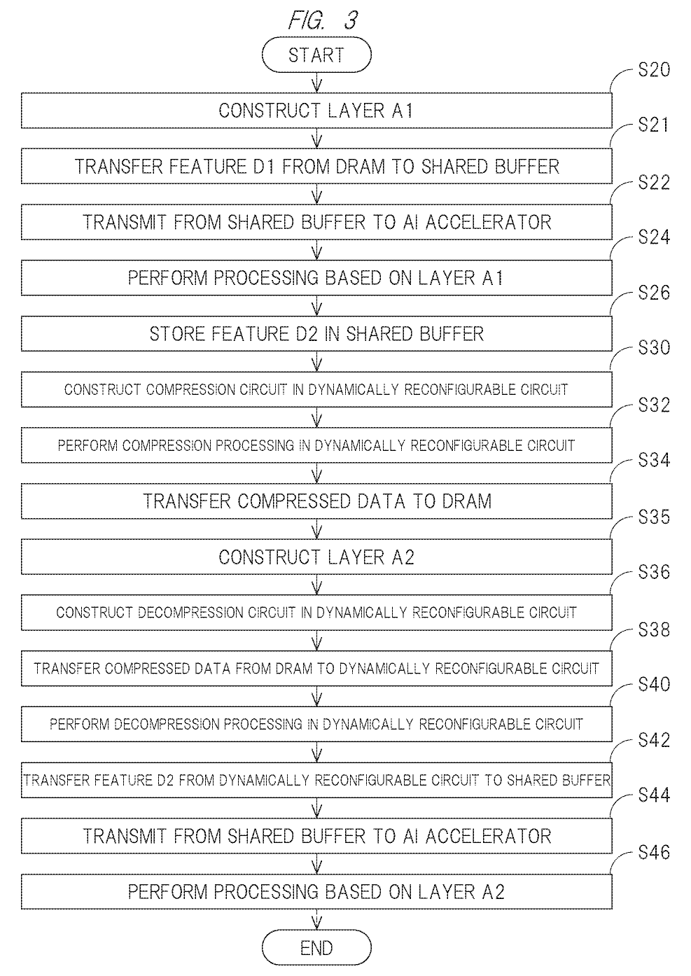

FIG. 3 is a flowchart illustrating processing of the MPU 100 according to the first embodiment. Referring to FIG. 3, the MPU 100 constructs the layer A1 of the AI model (step S20).

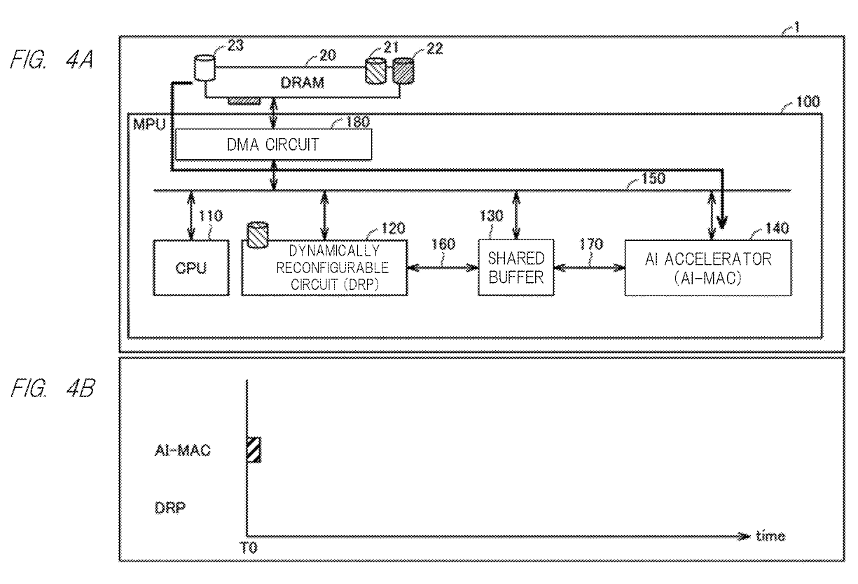

FIG. 4 is a diagram illustrating a flow (part 1) of processing according to the first embodiment. Referring to FIG. 4A, it is assumed that the DRAM 20 stores the feature D1 in advance. For example, the feature D1 may be initial value data. The DMA circuit 180 accesses the DRAM 20 in accordance with, for example, an instruction of the CPU 110 and transfers the AI model data 23 stored in the DRAM 20 to the AI accelerator 140. The AI accelerator 140 constructs the layer A1 of the AI model based on the AI model data 23.

Referring to FIG. 4B, a case where the AI model data 23 is transferred to the AI accelerator 140 at time T0 and the layer A1 of the AI model is constructed is illustrated.

Referring back to FIG. 3, the MPU 100 subsequently transfers the feature D1 from the DRAM 20 to the shared buffer 130 (step S21). Subsequently, the MPU 100 transmits data from the shared buffer 130 to the AI accelerator 140 (step S22).

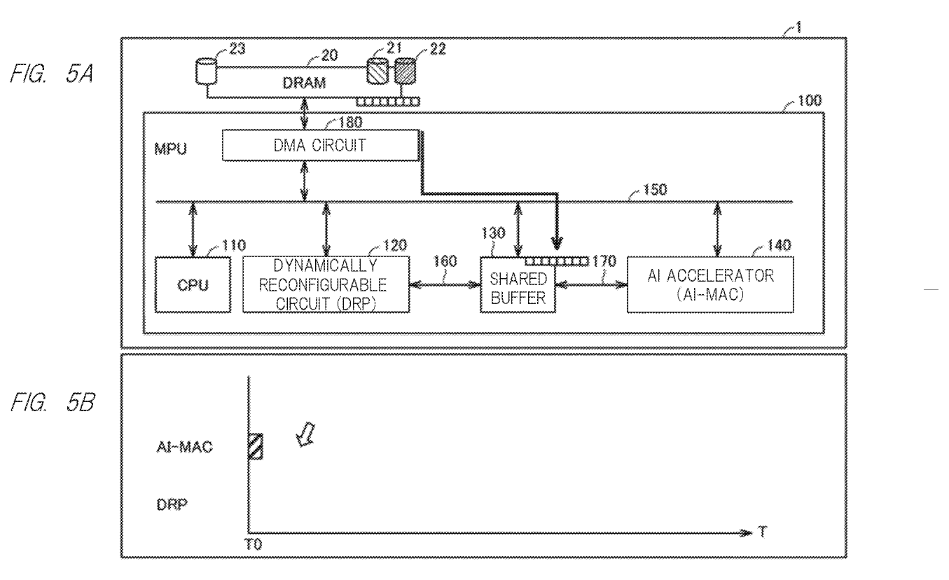

FIG. 5 is a diagram illustrating the flow (part 2) of the processing according to the first embodiment. Referring to FIG. 5A, specifically, the DMA circuit 180 acquires data of the feature D1 stored in the DRAM 20 in accordance with an instruction from the CPU 110, and transfers the data to the shared buffer 130 via the shared bus 150. Referring to FIG. 5B, the AI accelerator 140 is in a state of awaiting reception of data from the shared buffer 130 after the layer A1 of the AI model is constructed.

Referring back to FIG. 3, the MPU 100 subsequently transmits data from the shared buffer 130 to the AI accelerator 140 (step S22). Subsequently, the MPU 100 performs processing based on the layer A1 of the AI model (step S24). Subsequently, the MPU 100 stores a calculation result of the AI accelerator 140 in the shared buffer 130 (step S26).

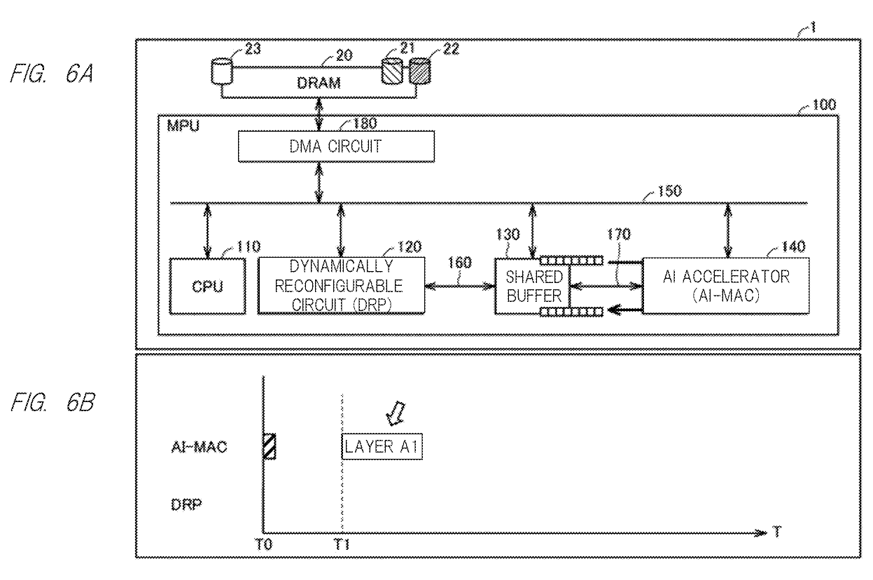

FIG. 6 is a diagram illustrating the flow (part 3) of the processing according to the first embodiment. Referring to FIG. 6A, the shared buffer 130 transmits data of the feature D1 to the AI accelerator 140 via the dedicated bus 170. The AI accelerator 140 follows a procedure of performing a product-sum operation of multiplying the data of the feature D1 that is the input data by a weight, performing an operation such as activation on the result, and outputting a calculation result. Then, the AI accelerator 140 transmits the data of the feature D2 that is a calculation result to the shared buffer 130. Referring to FIG. 6B, a case where a series of processing based on the layer A1 of the AI model is performed by the AI accelerator 140 at time T1 is illustrated.

Referring back to FIG. 3, the MPU 100 then constructs a compression circuit in the dynamically reconfigurable circuit 120 (step S30).

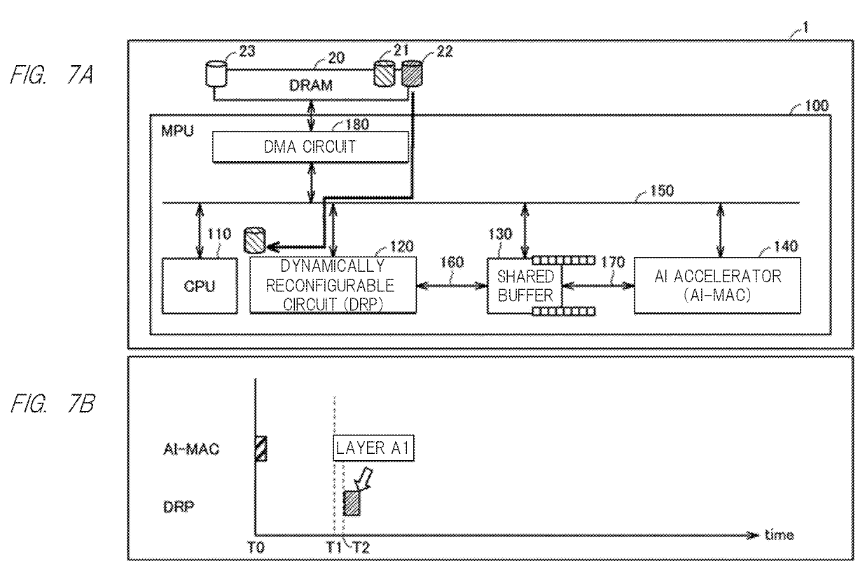

FIG. 7 is a diagram illustrating the flow (part 4) of the processing according to the first embodiment. Referring to FIG. 7A, during the processing between the shared buffer 130 and the AI accelerator 140, the DMA circuit 180 accesses the DRAM 20 in accordance with an instruction of the CPU 110, and transfers the compression program 21 stored in the DRAM 20 to the dynamically reconfigurable circuit 120. The dynamically reconfigurable circuit 120 constructs a compression circuit in accordance with the compression program 21. Referring to FIG. 7B, a case where the DMA circuit 180 transfers the compression program 21 stored in the DRAM 20 to the dynamically reconfigurable circuit 120 and constructs the compression circuit in accordance with the compression program 21 at time T2 is illustrated.

Referring back to FIG. 3, subsequently, the MPU 100 causes the dynamically reconfigurable circuit 120 to perform compression processing on the data of the feature D2 (step S32). Subsequently, the MPU 100 transfers the compressed data to the DRAM 20 (step S34).

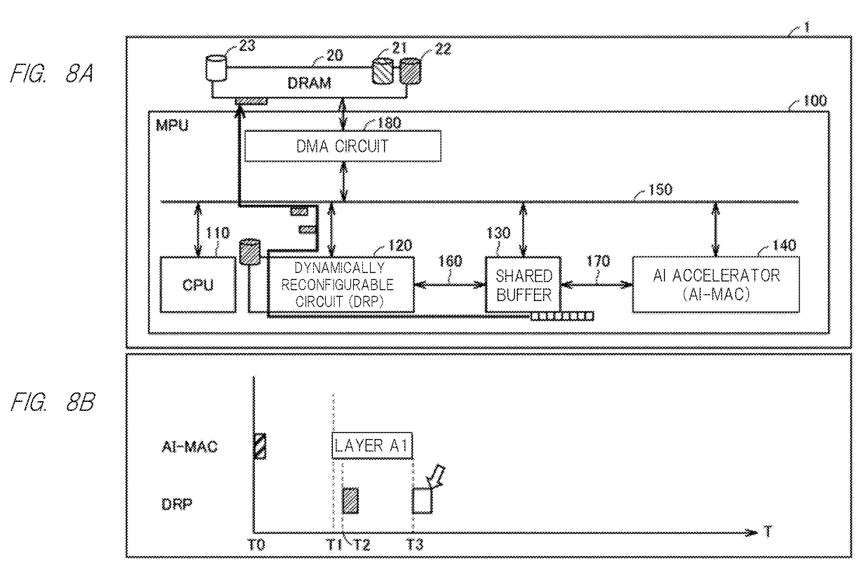

FIG. 8A and FIG. 8B are diagrams illustrating the flow (part 5) of the processing according to the first embodiment. Referring to FIG. 8A, the feature D2 is transmitted from the shared buffer 130 to the dynamically reconfigurable circuit 120. The dynamically reconfigurable circuit 120 operates as a compression circuit and stores the compressed data of the feature D2 in the DRAM 20 via the DMA circuit 180. Referring to FIG. 8B, a case where the dynamically reconfigurable circuit 120 performs compression processing and transfers the compressed data to the DRAM 20 via the DMA circuit 180 at time T3 after the processing of the AI accelerator 140 is illustrated.

Referring back to FIG. 3, the MPU 100 constructs the layer A2 of the AI model (step S35). Subsequently, the MPU 100 constructs a decompression circuit of the dynamically reconfigurable circuit 120 (step S36).

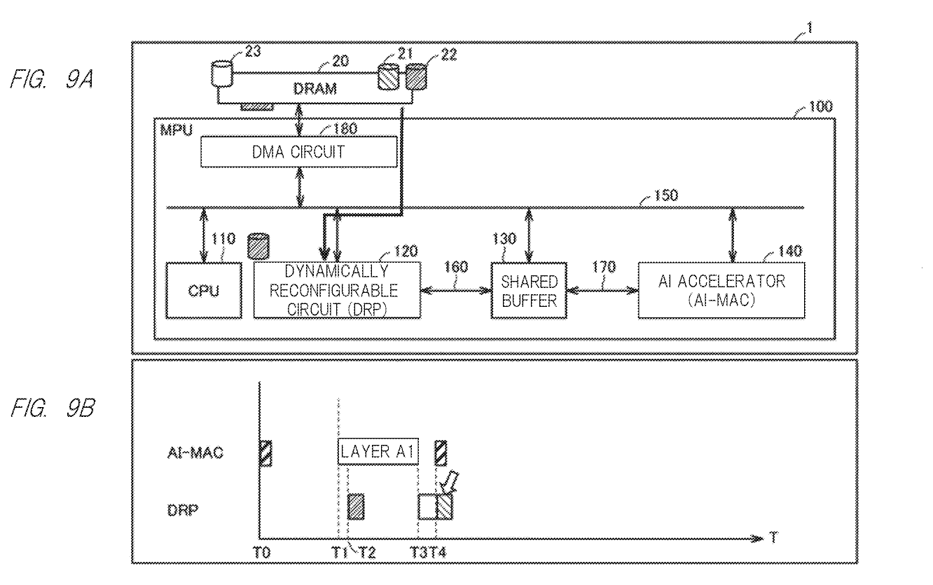

FIG. 9A and FIG. 9B are diagrams illustrating the flow (part 6) of the processing according to the first embodiment. Referring to FIG. 9A, the DMA circuit 180 accesses the DRAM 20 in accordance with an instruction of the CPU 110, and transfers the AI model data 23 stored in the DRAM 20 to the AI accelerator 140. The AI accelerator 140 constructs the layer A2 of the AI model based on the AI model data 23. Further, the DMA circuit 180 accesses the DRAM 20 in accordance with an instruction of the CPU 110, and transfers the decompression program 22 corresponding to the compression program 21 stored in the DRAM 20 to the dynamically reconfigurable circuit 120. The dynamically reconfigurable circuit 120 constructs a decompression circuit in accordance with the decompression program 22. Referring to FIG. 9B, after the compressed data of the feature D2 is stored in the DRAM 20, the DMA circuit 180 accesses the DRAM 20 in accordance with an instruction of the CPU 110 and transfers the AI model data 23 stored in the DRAM 20 to the AI accelerator 140 at time T4. The AI accelerator 140 constructs the layer A2 of the AI model based on the AI model data 23. A case where the DMA circuit 180 transfers the decompression program 22 stored in the DRAM 20 to the dynamically reconfigurable circuit 120 in accordance with an instruction of the CPU 110 and constructs the decompression circuit in accordance with the decompression program 22 is illustrated.

Referring back to FIG. 3, the MPU 100 subsequently transfers the compressed data stored in the DRAM 20 serving as the external memory to the dynamically reconfigurable circuit 120 (step S38). Subsequently, the MPU 100 performs decompression processing in the dynamically reconfigurable circuit 120 (step S40). Subsequently, the MPU 100 transmits the decompressed feature D2 from the dynamically reconfigurable circuit 120 to the shared buffer 130 (step S42).

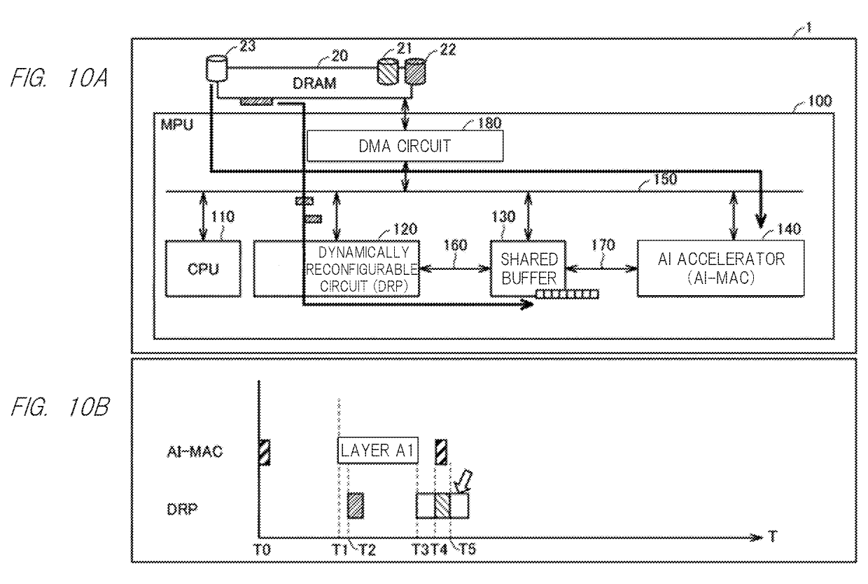

FIG. 10A and FIG. 10B are diagrams illustrating the flow (part 7) of the processing according to the first embodiment. Referring to FIG. 10A, the dynamically reconfigurable circuit 120 decompresses the compressed data in accordance with, for example, an instruction of the CPU 110 and transmits the decompressed data to the shared buffer 130. Referring to FIG. 10B, a case where the compressed data is decompressed by the dynamically reconfigurable circuit 120 and the decompressed data of the feature D2 is stored in the shared buffer 130 at time T5 is illustrated. Note that the dynamically reconfigurable circuit 120 may decompress the compressed data in accordance with a program read in advance without passing through the CPU 110 and transmit the decompressed data to the shared buffer 130.

Referring back to FIG. 3, the MPU 100 subsequently transmits the feature D2 decompressed from the shared buffer 130 to the AI accelerator 140 (step S44).

Subsequently, the MPU 100 performs processing based on the layer A2 of the AI model (step S46). Thereafter, processing similar to that described in step S26 is performed.

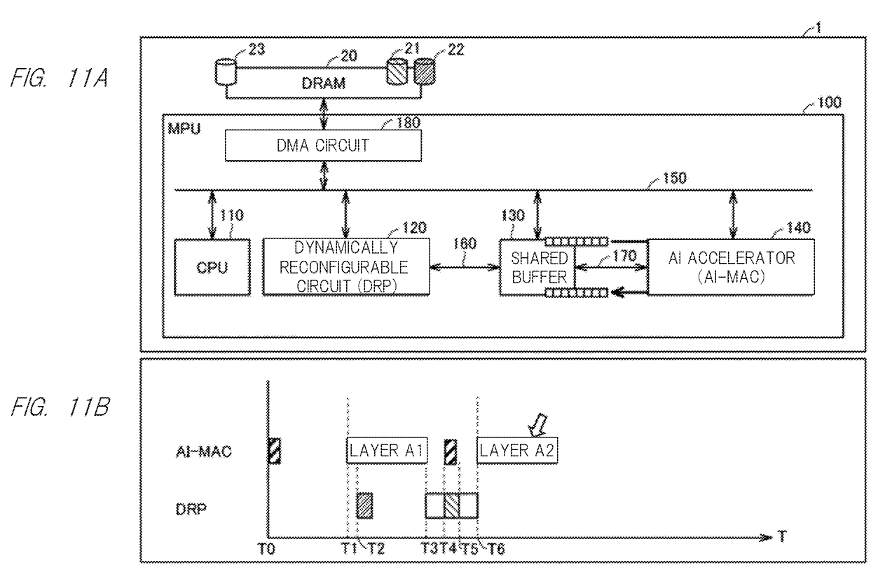

FIG. 11A and FIG. 11B are diagrams illustrating the flow (part 8) of the processing according to the first embodiment. Referring to FIG. 11A, the shared buffer 130 transmits data of the feature D2 to the AI accelerator 140 via the dedicated bus 170. The AI accelerator 140 follows a procedure of performing a product-sum operation of multiplying the data of the feature D2 that is the input data by a weight, performing an operation such as activation on the result, and outputting a calculation result. Then, the AI accelerator 140 transmits the data of the feature D3 that is the calculation result, to the shared buffer 130. Referring to FIG. 11B, a case where a series of processing based on the layer A1 of the AI model is performed by the AI accelerator 140 at time T6 is illustrated.

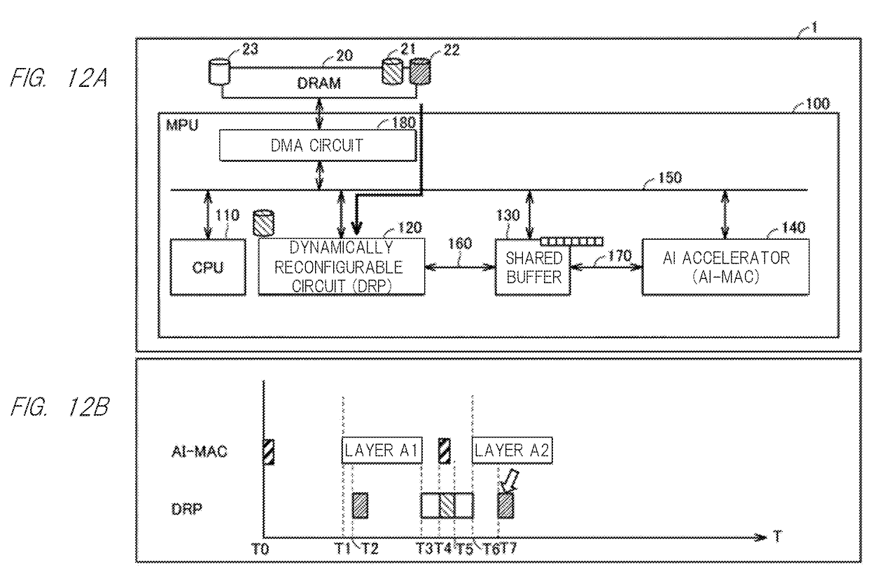

FIG. 12A and FIG. 12B are diagrams illustrating the flow (part 9) of the processing according to the first embodiment. Referring to FIG. 12A, during the processing between the shared buffer 130 and the AI accelerator 140, the DMA circuit 180 accesses the DRAM 20 in accordance with an instruction of the CPU 110, and transfers the compression program 21 stored in the DRAM 20 to the dynamically reconfigurable circuit 120. The dynamically reconfigurable circuit 120 constructs a compression circuit in accordance with the compression program 21. Referring to FIG. 12B, a case where the DMA circuit 180 transfers the compression program 21 stored in the DRAM 20 to the dynamically reconfigurable circuit 120, and constructs the compression circuit in accordance with the compression program 21 at time T7 is illustrated.

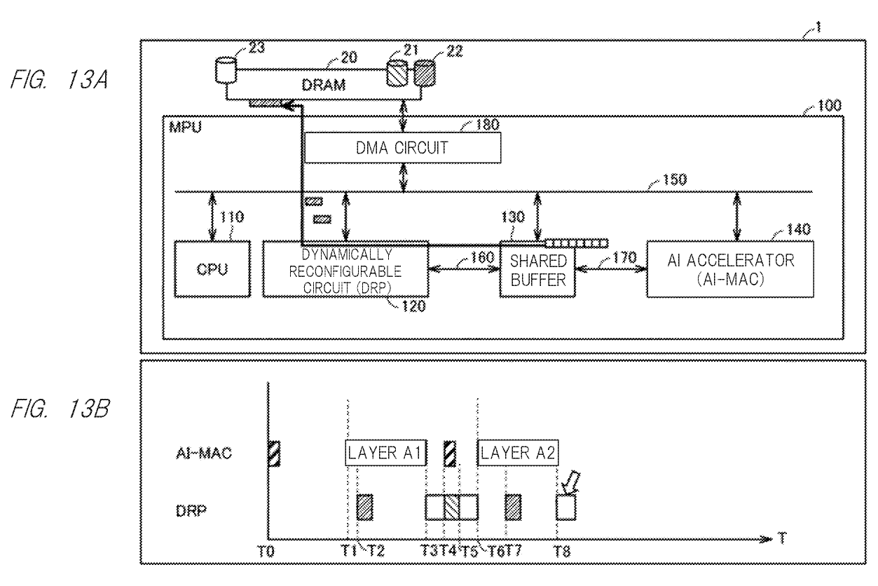

FIG. 13A and FIG. 13B are diagrams illustrating the flow (part 10) of the processing according to the first embodiment. Referring to FIG. 13A, the feature D3 is transmitted from the shared buffer 130 to the dynamically reconfigurable circuit 120. The dynamically reconfigurable circuit 120 operates as a compression circuit and stores the compressed data of the feature D3 in the DRAM 20 via the DMA circuit 180. Referring to FIG. 13B, a case where the dynamically reconfigurable circuit 120 performs compression processing and transfers the compressed data to the DRAM 20 via the DMA circuit 180 at time T8 after the processing of the AI accelerator 140 is illustrated.

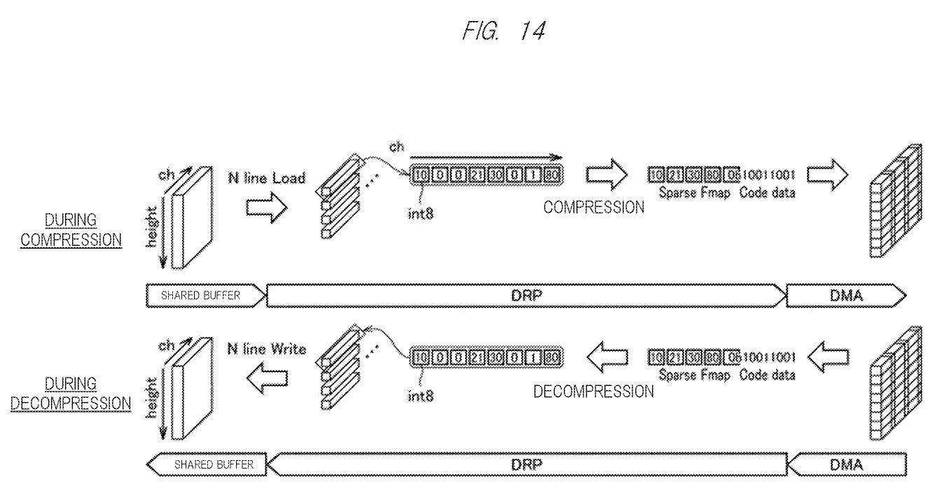

FIG. 14 is a diagram illustrating an example of compression processing performed by the dynamically reconfigurable circuit 120 according to the first embodiment. For example, sparse data compression will be described. Referring to FIG. 14, as an example, a scheme of compressing data by decomposing a data group input to the shared buffer 130 into 8-bit units and transferring code data indicating positions of 0 without transferring values of 0 is illustrated. Conversely, a scheme of decompressing data compressed based on the coded data is illustrated. Accordingly, the amount of data at the time of transfer can be reduced.

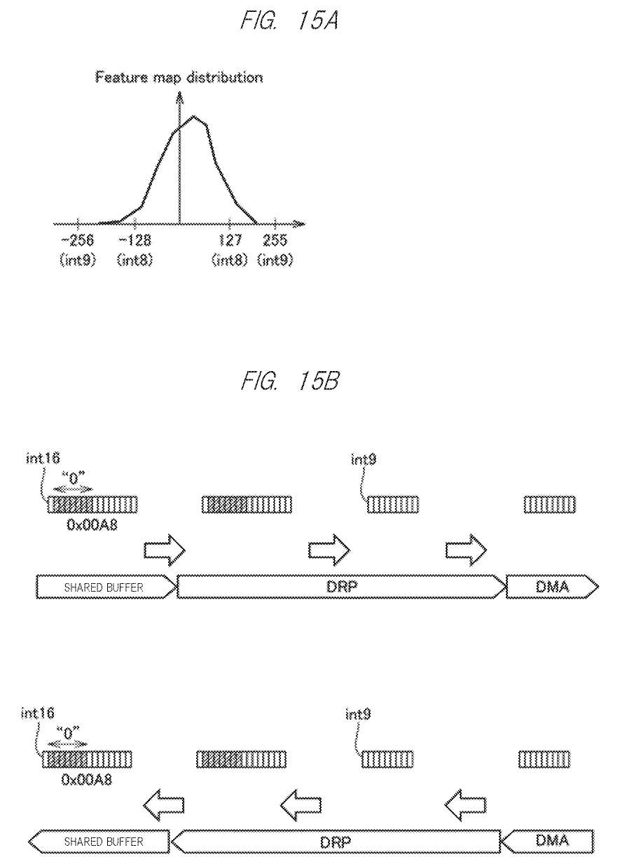

FIG. 15A and FIG. 15B are diagrams illustrating another example of the compression processing performed by the dynamically reconfigurable circuit 120 according to the first embodiment. As an example, bit packing compression will be described. Referring to FIG. 15A, here, a case where data falls within 9 bits as a data distribution is illustrated. In this situation, a case where 16 bits are used as the calculation processing is illustrated. In this case, since valid bits are 9 bits, 7 bits are deleted, and 9-bit data transfer is performed with the DRAM 20. Accordingly, the amount of data at the time of transfer can be reduced. In contrast, in the case of decompression, 16 bits may be output by formally adding 7 bits to 9 bits of data in the case of decompression by the dynamically reconfigurable circuit 120.

The compression processing and the decompression processing above are examples, and the present invention is not limited thereto. Processing such as run-length encoding and Huffman coding may be used.

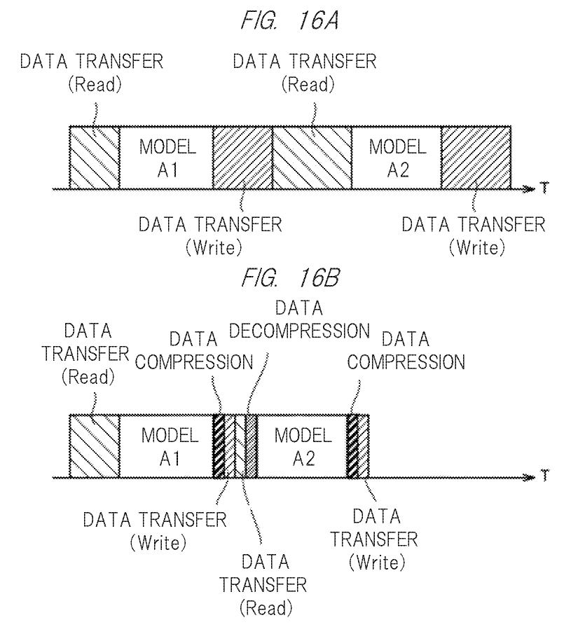

FIG. 16A and FIG. 16B are diagrams illustrating a processing time of the information processing system 1 according to a comparative example and the first embodiment. Referring to FIG. 16A, a processing time of the information processing system according to the comparative example is illustrated. In the information processing system according to the comparative example, each unit is connected by a shared bus, and the dedicated bus 160 provided between the shared buffer 130 and the dynamically reconfigurable circuit 120 and the dedicated bus 170 provided between the shared buffer 130 and the AI accelerator 140 are not provided. Here, the data transfer (Read) means processing for reading data from the DRAM and transferring the data to the AI accelerator. Data transfer (Write) means processing for transferring data from the AI accelerator to the DRAM for writing. In the case of this configuration, since only the shared bus is used for data transfer, there is a possibility that a significant amount of time may be required for data transfer.

The information processing system 1 according to the first embodiment has a configuration in which the dedicated bus 160 is provided between the shared buffer 130 and the dynamically reconfigurable circuit 120 and the dedicated bus 170 is provided between the shared buffer 130 and the AI accelerator 140. Accordingly, it is possible to greatly reduce the time required for data transfer with the shared buffer.

The first data transfer (Read) means processing for reading data from the DRAM 20 and transferring the data to the AI accelerator 140. Since the first data is data before compression, there is a possibility that data transfer may take some time. On the other hand, information regarding the processed data of the AI accelerator 140 is transmitted to the dynamically reconfigurable circuit 120 via the dedicated buses 160 and 170 and is compressed by the dynamically reconfigurable circuit 120, and the compressed data is written to the DRAM 20. Further, since the data amount of compressed data stored in the DRAM 20 is small, a time to transfer the compressed data to the dynamically reconfigurable circuit 120 is also shortened. Since the data decompressed by the dynamically reconfigurable circuit 120 is transmitted to the AI accelerator 140 via the dedicated buses 160 and 170, it is possible to start data processing based on the AI model early. Accordingly, the information processing system 1 according to the present disclosure can perform high-speed data processing.

In the present example, for example, the case where the DMA circuit 180 accesses the DRAM 20 in accordance with the instruction of the CPU 110 and executes various operations has been described, but the present invention is not limited thereto. For example, the dynamically reconfigurable circuit (DRP) starts an operation by loading a program stored in the DRAM 20 in accordance with an instruction of the CPU 110, but an execution procedure with the DMA circuit 180 may be set in the program in advance. For example, the dynamically reconfigurable circuit (DRP) may directly give an instruction to the DMA circuit 180 without passing through the CPU 110. Further, the AI accelerator 140 starts an operation by loading a program stored in the DRAM 20 in accordance with an instruction of the CPU 110, but an execution procedure with the DMA circuit 180 may be set in the program in advance. For example, the AI accelerator 140 may directly give an instruction to the DMA circuit 180 without passing through the CPU 110. The same applies to the following.

### Second Embodiment

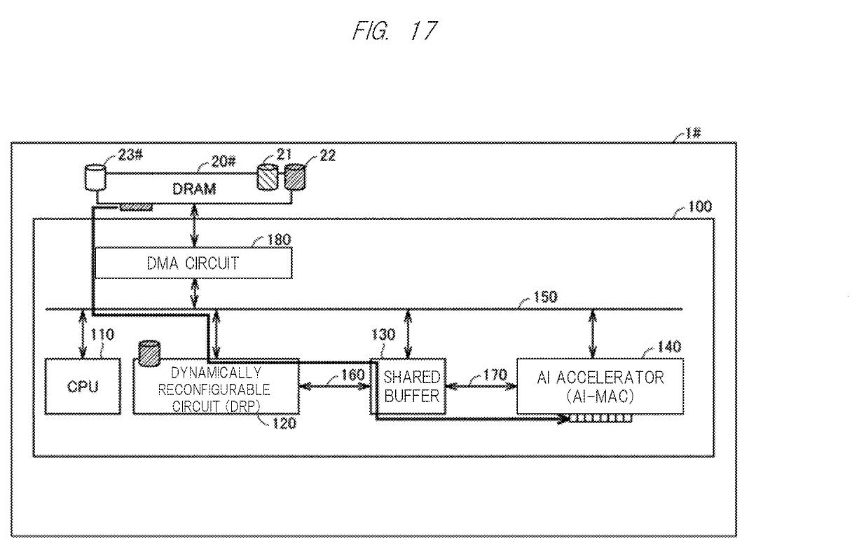

FIG. 17 is a block diagram illustrating a hardware configuration of an information processing system 1# according to a second embodiment. Referring to FIG. 17, the information processing system 1# is different in that the DRAM 20 is replaced with a DRAM 20#. The DRAM 20# stores compressed AI model data 23# of the AI accelerator 140.

In this configuration, the DMA circuit 180 accesses the DRAM 20# in accordance with an instruction of the CPU 110, and transfers the compressed AI model data 23# stored in the DRAM 20# to the dynamically reconfigurable circuit 120. The dynamically reconfigurable circuit 120 decompresses the compressed AI model data 23# and transfers the decompressed AI model data 23# to the AI accelerator 140 via the shared buffer 130. Since the data transferred from the DRAM 20# to the dynamically reconfigurable circuit 120 is compressed data, the transfer time can be shortened. Further, the AI model data 23# decompressed by the dynamically reconfigurable circuit 120 is transmitted to the AI accelerator 140 using the dedicated buses 160 and 170. Accordingly, the AI accelerator 140 can construct a layer of the AI model early based on the decompressed AI model data 23#.

### Third Embodiment

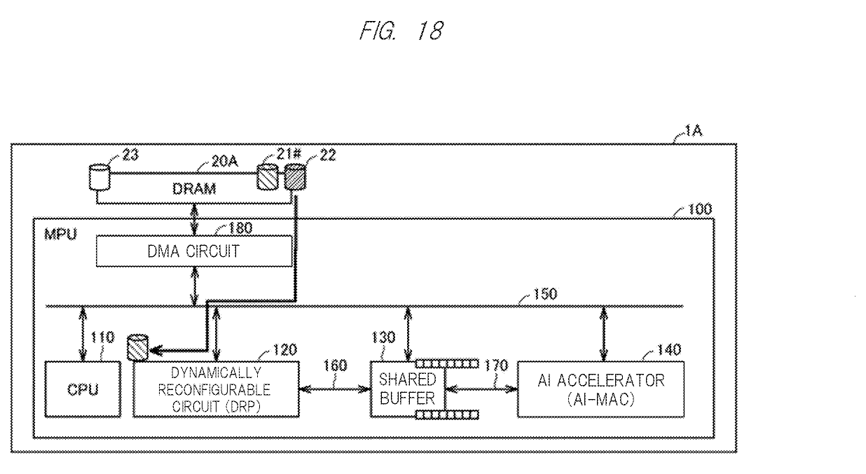

FIG. 18 is a block diagram illustrating a hardware configuration of an information processing system 1A according to a third embodiment. Referring to FIG. 18, the information processing system 1A is different in that the DRAM 20 is replaced with a DRAM 20A. The DRAM 20A stores a compression program 21#. The compression program 21# constructs both a function of activation function processing and a function of a compression circuit in the dynamically reconfigurable circuit 120. Specifically, the dynamically reconfigurable circuit 120 performs compression processing on the data subjected to the activation function processing.

In this configuration, the DMA circuit 180 accesses the DRAM 20A in accordance with an instruction from the CPU 110, and transfers the compression program 21# stored in the DRAM 20A to the dynamically reconfigurable circuit 120. The dynamically reconfigurable circuit 120 constructs an activation function processing circuit and a compression circuit in accordance with the compression program 21#. For example, the dynamically reconfigurable circuit 120 performs rectified linear unit (ReLu) processing as activation function processing on the data transmitted from the shared buffer 130, and compresses the processed data. ReLu is a function in which an output value is always 0 when the input value to the function is 0 or less and the output value is the same value as the input value when the input value is more than 0.

By constructing and combining the dynamically reconfigurable circuit 120 with other processing circuits other than the compression circuit, it is possible to further increase an overall processing speed.

In the present example, the case in which the activation function processing and the compression processing are combined has been described, but the present invention is not limited thereto, and the compression processing may be performed in combination with other processing.

### Fourth Embodiment

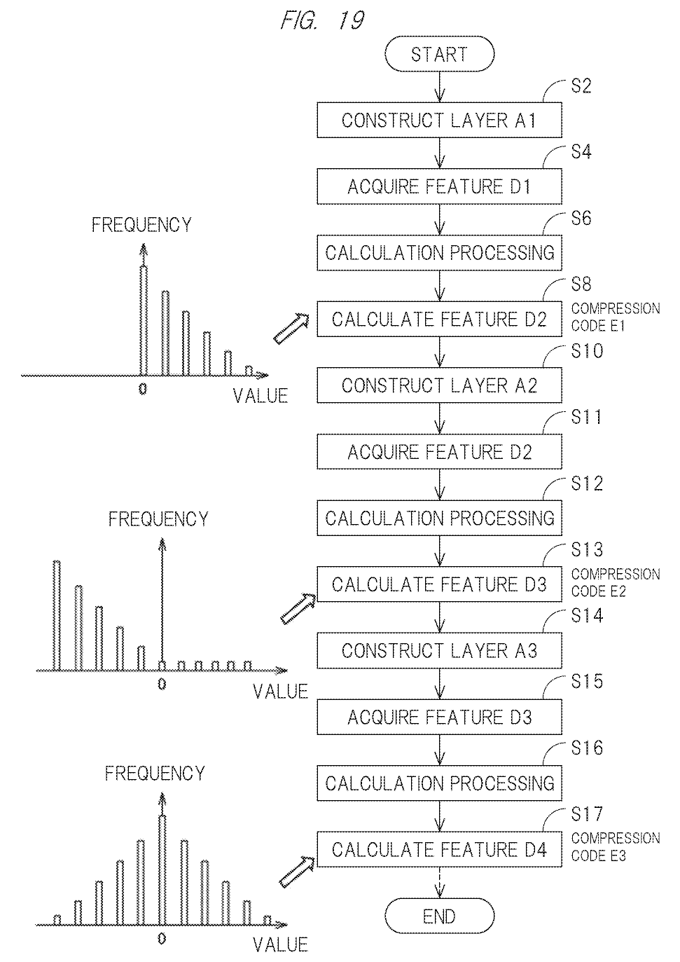

FIG. 19 is a flowchart illustrating a calculation processing operation of deep learning using the AI accelerator 140 according to a fourth embodiment. A flow diagram similar to that described in FIG. 2 is illustrated. Here, distribution examples of the calculated features D2 to D4 are illustrated.

Specifically, data of the feature D2 has characteristics in which a frequency peaks at0 and diminishes as the value increases. Also, the data of the feature D3 has characteristics in which the frequency increases as the value decreases from 0. Further, the data of the feature D4 has characteristics in which the frequency decreases uniformly as the value moves away from 0.

As illustrated in the distribution, the data distribution configuration differs in accordance with the feature. That is, a suitable compression scheme is also different in accordance with the data distribution. For example, a compression rate of a compression code E1 is high for the data of the feature D2. Also, a compression rate of a compression code E2 is high for the data of the feature D3. Further, a compression rate of a compression code E3 is high for the data of the feature D4.

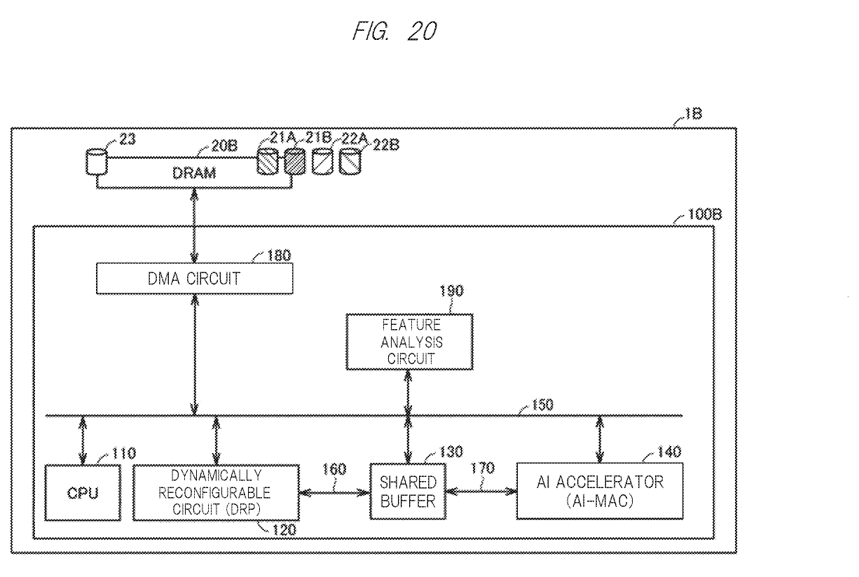

FIG. 20 is a diagram illustrating a hardware configuration of an information processing system 1B according to the fourth embodiment. Referring to FIG. 20, the information processing system 1B is different from the information processing system 1 in that the DRAM 20 is replaced with a DRAM 20B and the MPU 100 is replaced with an MPU 100B. The DRAM 20B stores a plurality of types of compression and decompression programs as compared with the DRAM 20. Specifically, compression programs 21A and 21B that cause the dynamically reconfigurable circuit 120 to function as a compression circuit and decompression programs 22A and 22B that cause the dynamically reconfigurable circuit to function as a decompression circuit are stored. Note that the present invention is not limited thereto, and additional types of compression programs and decompression programs may be stored.

The MPU 100B is different from the MPU 100 in that a feature analysis circuit 190 is further included. Other configurations are the same as those described with reference to FIG. 1, and the detailed descriptions thereof will not be repeated.

The feature analysis circuit 190 analyzes the feature of the calculation result of the AI accelerator 140 stored in the shared buffer 130. Specifically, as described with reference to FIG. 19, the feature analysis circuit analyzes the data distribution of the feature, and outputs information regarding a suitable compression code as an analysis result to the CPU 110.

The CPU 110 gives an instruction to the DMA circuit 180 based on, for example, the compression code information from the feature analysis circuit 190. Specifically, the DMA circuit 180 accesses the DRAM 20B in accordance with an instruction of the CPU 110, and transfers an optimum compression program among a plurality of types of compression programs stored in the DRAM 20B to the dynamically reconfigurable circuit 120. For example, the optimum compression program is selected from the compression programs 21A and 21B stored in the DRAM 20B and transferred to the dynamically reconfigurable circuit 120. For example, the compression program 21A is selected and transferred to the dynamically reconfigurable circuit 120. Similarly, the DMA circuit 180 accesses the DRAM 20B in accordance with an instruction of the CPU 110, and transfers an optimum decompression program among a plurality of types of decompression programs stored in the DRAM 20B to the dynamically reconfigurable circuit 120. For example, the optimum decompression program is selected from the decompression programs 22A and 22B stored in the DRAM 20B and transferred to the dynamically reconfigurable circuit 120. For example, the decompression program 22A is selected and transferred to the dynamically reconfigurable circuit 120.

In the present example, the case where the DMA circuit 180 accesses the DRAM 20B in accordance with the instruction of the CPU 110 has been described, for example, but the present invention is not limited thereto. For example, the feature analysis circuit 190 may access the DMA circuit 180 without passing through the CPU 110 based on information regarding the compression code in accordance with a program read in advance, and the DMA circuit 180 may transfer the optimum compression program among a plurality of types of compression programs stored in the DRAM 20B to the dynamically reconfigurable circuit 120.

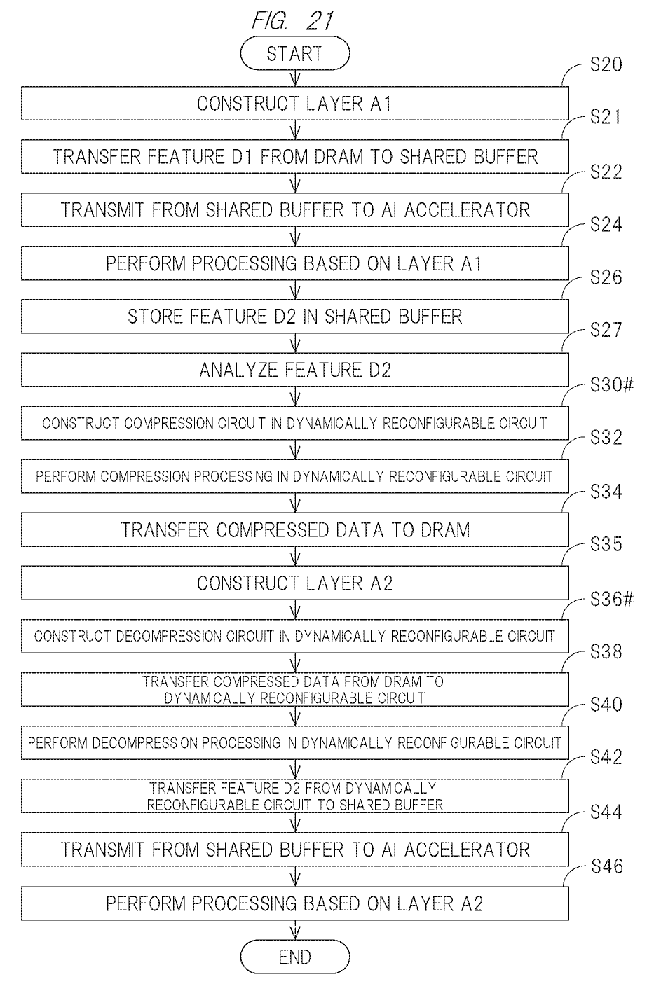

FIG. 21 is a flowchart illustrating processing of the MPU 100 according to the fourth embodiment. Referring to FIG. 21, the flowchart of the fourth embodiment is different from the flowchart of FIG. 3 in that step S27 is added and steps S30 and S36 are replaced with steps S30# and S36#. Other configurations are similar to those described with reference to FIG. 3, and the detailed descriptions thereof will not be repeated.

In step S26, after the calculation result of the AI accelerator 140 is stored in the shared buffer 130, the MPU 100 analyzes the feature D2 (step S27). Specifically, the feature analysis circuit 190 analyzes the feature of the calculation result of the AI accelerator 140 stored in the shared buffer 130. Specifically, as described with reference to FIG. 19, the feature analysis circuit 190 analyzes the data distribution of the feature, and outputs information regarding a suitable compression code as an analysis result to the CPU 110.

Subsequently, the MPU 100 constructs a compression circuit in the dynamically reconfigurable circuit (step S30#). Specifically, the CPU 110 gives an instruction to the DMA circuit 180 based on the information regarding the compression code from the feature analysis circuit 190. The DMA circuit 180 accesses the DRAM 20B in accordance with an instruction of the CPU 110, selects an optimum compression program from the compression programs 21A and 21B stored in the DRAM 20B, and transfers the selected compression program to the dynamically reconfigurable circuit 120. For example, it is assumed that the compression program 21A is selected. The dynamically reconfigurable circuit 120 constructs a compression circuit in accordance with the compression program 21A.

Subsequently, the MPU 100 performs compression processing on the data of the feature D2 in the dynamically reconfigurable circuit 120 (step S32). Subsequently, the MPU 100 transfers the compressed data to the DRAM 20 (step S34). Subsequently, the MPU 100 constructs the layer A2 of the AI model (step S35). Subsequently, the MPU 100 constructs a decompression circuit of the dynamically reconfigurable circuit 120 (step S36#). The CPU 110 gives an instruction to the DMA circuit 180 based on the information regarding the compression code from the feature analysis circuit 190. The DMA circuit 180 accesses the DRAM 20B in accordance with an instruction of the CPU 110, selects an optimum decompression program from the decompression programs 22A and 22B stored in the DRAM 20B, and transfers the selected decompression program to the dynamically reconfigurable circuit 120. For example, it is assumed that the decompression program 22A corresponding to the compression program 21A is selected. The dynamically reconfigurable circuit 120 constructs a decompression circuit in accordance with the decompression program 22A.

Since the subsequent processing is basically similar to that described with reference to FIG. 3, the detailed descriptions thereof will not be repeated.

With this configuration, it is possible to construct a compression circuit and a decompression circuit optimum for the calculated feature in the dynamically reconfigurable circuit 120, and it is possible to suppress the data transfer amount and to further speed up the entire processing.

Although this disclosure has been specifically described above based on the embodiments, this disclosure is not limited to the embodiments, and various modifications can be made within the range not departing from the gist of this disclosure.

What is claimed is:

1. An information processing device comprising:
a dynamically reconfigurable processor capable of dynamically reconfiguring processing content;
an accelerator configured to speed up inference of an AI model;
a shared buffer provided between the dynamically reconfigurable processor and the accelerator and connected thereto by dedicated first and second buses, respectively;
a shared bus connected to the dynamically reconfigurable processor, the accelerator, and the shared buffer; and
a transfer circuit connected to an external memory and capable of transferring data using the shared bus,
wherein a calculation result of the accelerator is stored in the shared buffer via the second bus,
wherein the dynamically reconfigurable processor receives the calculation result of the accelerator stored in the shared buffer via the first bus and compresses the received calculation result, and
wherein the transfer circuit transfers compressed data via the shared bus to be stored in the external memory.

2. The information processing device according to claim 1,
wherein the external memory includes a compression program for reconfiguring the dynamically reconfigurable processor into a compression circuit that compresses input data and a decompression program for reconfiguring the dynamically reconfigurable processor into a decompression circuit that decompresses input data,
wherein, after being reconfigured into the decompression circuit in accordance with the decompression program, the dynamically reconfigurable processor receives input of the compressed data stored in the external memory and decompresses the compressed data, and transmits the decompressed data to the accelerator via the shared buffer, and
wherein, after being reconfigured into the compression circuit in accordance with the compression program, the dynamically reconfigurable processor receives the calculation result of the accelerator via the shared buffer and compresses the calculation result.

3. The information processing device according to claim 1,
wherein the dynamically reconfigurable processor transfers the compressed data via the shared bus by burst transfer to be stored in the external memory.

4. The information processing device according to claim 1,
wherein the dynamically reconfigurable processor receives input of the compressed data from the external memory via the shared bus by burst transfer and decompresses the compressed data, and transmits the decompressed data to the shared buffer via the first bus.

5. The information processing device according to claim 1,
wherein the external memory includes a plurality of compression programs for reconfiguring the dynamically reconfigurable processor corresponding to each of a plurality of AI models into a compression circuit that compresses input data and a plurality of decompression programs for reconfiguring the dynamically reconfigurable processor into a decompression circuit that decompresses input data,
wherein, after being reconfigured into the decompression circuit in accordance with the decompression program corresponding to an AI model, the dynamically reconfigurable processor receives input of the compressed data stored in the external memory and decompresses the compressed data, and transmits the decompressed data to the accelerator via the shared buffer, and
wherein, after being reconfigured into the compression circuit in accordance with the compression program corresponding to the AI model, the dynamically reconfigurable processor receives the calculation result of the accelerator via the shared buffer and compresses the calculation result.

6. The information processing device according to claim 1,
wherein the external memory stores compressed weight data used to construct the AI model of the accelerator,
wherein, after being reconfigured into the decompression circuit in accordance with the decompression program, the dynamically reconfigurable processor receives input of the compressed weight data stored in the external memory and decompresses the compressed weight data, and transmits the decompressed weight data to the accelerator via the shared buffer, and
wherein the accelerator constructs the AI model in accordance with the weight data.

7. The information processing device according to claim 1,
wherein the compression program is a program for reconfiguring the dynamically reconfigurable processor into a compression circuit that compresses input data after performing activation function processing thereon, and
wherein, after being reconfigured into the compression circuit in accordance with the compression program, the dynamically reconfigurable processor receives a calculation result of the accelerator via the shared buffer and compresses data to which activation function is applied, and transfer the compressed data via the shared bus to be stored in the external memory.

8. The information processing device according to claim 1,
wherein the external memory includes a plurality of compression programs for reconfiguring the dynamically reconfigurable processor into a compression circuit that compresses input data and a plurality of decompression programs for reconfiguring the dynamically reconfigurable processor into a decompression circuit that decompresses input data,
the information processing device further comprising an analysis unit configured to analyze a feature of the calculation result of the accelerator stored in the shared buffer,
wherein, after being reconfigured into the compression circuit in accordance with a compression program selected from the plurality of compression programs based on an analysis result of the analysis unit, the dynamically reconfigurable processor receives the calculation result of the accelerator via the shared buffer and compresses the calculation result, and
wherein, after being reconfigured into the decompression circuit in accordance with a decompression program selected from the plurality of decompression programs based on the analysis result of the analysis unit, the dynamically reconfigurable processor receives input of the compressed data stored in the external memory and decompresses the compressed data, and transmits the decompressed data to the accelerator via the shared buffer.

9. An information processing system comprising:
a dynamically reconfigurable processor capable of dynamically reconfiguring processing content;
an accelerator configured to speed up inference of an AI model;
a shared buffer provided between the dynamically reconfigurable processor and the accelerator and connected thereto by dedicated first and second buses, respectively;
a shared bus connected to the dynamically reconfigurable processor, the accelerator, and the shared buffer; and
a transfer circuit connected to an external memory and capable of transferring data using the shared bus,
wherein a calculation result of the accelerator is stored in the shared buffer via the second bus,
wherein the dynamically reconfigurable processor receives the calculation result of the accelerator stored in the shared buffer via the first bus and compresses the received calculation result, and
wherein the transfer circuit transfers compressed data via the shared bus to be stored in the external memory.
